(19) United States
(12) Patent Application Publication
(10) Pub. No.: US 2009/0078199 A1
(43) Pub. Date: Mar. 26, 2009

(54) Plasma enhanced chemical vapor deposition apparatus

(75) Inventors: Tsu Chun Tseng, Taoyuan Hsien (TW); Hwang Chi Lin, Taoyuan Hsien (TW); Shang Chu Cheng, Taoyuan Hsien (TW)

Correspondence Address: CHARLES E. BAXLEY, ESQUIRE, 90 JOHN STREET, SUITE 309, NEW YORK, NY, 10038, US

(73) Assignee: Innovation Vacuum Technology Co., Ltd.

(21) Appl. No.: 11/903,547

(22) Filed: Sep. 21, 2007

(51) Int. Cl. C23C 16/00

(52) U.S. Cl. 118/719

(57) ABSTRACT

A plasma enhanced chemical vapor deposition apparatus includes a receptacle having three chambers as an entering chamber, an intermediate chamber, and an exit chamber, four gates disposed before or behind or between the chambers for selectively closing the chambers and for allowing the chambers to be selectively vacuumed, one or more pumps coupled to each chamber for vacuuming each chamber, and for allowing the substrates to be treated with different processes or procedures in different chambers simultaneously and thus for allowing the time for treating the substrate to be greatly saved or economized, and thus for allowing the productivity to be greatly increased.

### BACKGROUND OF THE INVENTION

1. Field of the Invention

The present invention relates to a plasma enhanced chemical vapor deposition (PEVCD) apparatus, and more particularly to a plasma enhanced chemical vapor deposition apparatus including three chambers disposed or arranged side by side for facilitating the operating processes or procedures for the plasma enhanced chemical vapor deposition apparatus and for reducing the operating time for the plasma enhanced chemical vapor deposition apparatus.

2. Description of the Prior Art

Typical plasma enhanced chemical vapor deposition apparatuses comprise a vacuum receptacle having a single chamber formed therein for receiving the substrates and for conducting or operating the plasma enhanced chemical vapor deposition processes or procedures.

For example, U.S. Pat. No. 7,138,343 to Kadlec et al. discloses one of the typical plasma enhanced chemical vapor deposition apparatuses comprising an inhomogeneous plasma with a density distribution is generated and moved relative to the substrate for conducting a treatment using a vacuum treatment process.

However, when moving the substrate into and out of the vacuum receptacle, the vacuum receptacle should be opened and the vacuum status should be released, and it may take a long time to vacuum the vacuum receptacle, and it may thus take a long time to conduct or operate the plasma enhanced chemical vapor deposition processes or procedures.

The present invention has arisen to mitigate and/or obviate the afore-described disadvantages of the conventional plasma enhanced chemical vapor deposition apparatuses.

### SUMMARY OF THE INVENTION

The primary objective of the present invention is to provide a plasma enhanced chemical vapor deposition apparatus including three chambers disposed or arranged side by side for facilitating the operating processes or procedures for the plasma enhanced chemical vapor deposition apparatus and for reducing the operating time for the plasma enhanced chemical vapor deposition apparatus.

In accordance with one aspect of the invention, there is provided a plasma enhanced chemical vapor deposition apparatus comprising a receptacle including a first chamber as an entering chamber, a second chamber as an intermediate chamber, a third chamber as an exit chamber, the second chamber being arranged between the first chamber and the third chamber for selectively receiving substrates, a first gate disposed before the first chamber for closing the first chamber, a second gate disposed between the first and the second chambers for closing the first chamber, a third gate disposed between the second and the third chambers for closing the second chamber, a fourth gate disposed behind the third chamber for closing the second chamber and for allowing the first and the second and the third chambers to be selectively vacuumed, at least one first pump coupled to the first chamber for vacuuming the first chamber, at least one second pump coupled to the second chamber for vacuuming the second chamber, at least one third pump coupled to the third chamber for vacuuming the third chamber, a gas supply device coupled to the second chamber for supplying a gas into the second chamber and treating the substrates with a plasma enhanced chemical vapor deposition process, and an electrode attached to the second chamber for generating an electric field to act on the gas and the substrates.

The first pump and the second pump and the third pump may either be the dry pumps or the turbulent molecular pumps.

The receptacle includes at least one heater attached to the first chamber for heating the substrates. The receptacle includes at least one cooling device attached to the third chamber for cooling the substrates.

Further objectives and advantages of the present invention will become apparent from a careful reading of the detailed description provided hereinbelow, with appropriate reference to the accompanying drawings.

### BRIEF DESCRIPTION OF THE DRAWINGS

FIG. 1 is a plan schematic view of a plasma enhanced chemical vapor deposition apparatus in accordance with the present invention; and

FIGS. 2, 3, 4, 5, 6, 7, 8 are plan schematic views similar to FIG. 1, illustrating the operation of the plasma enhanced chemical vapor deposition apparatus.

### DETAILED DESCRIPTION OF THE PREFERRED EMBODIMENT

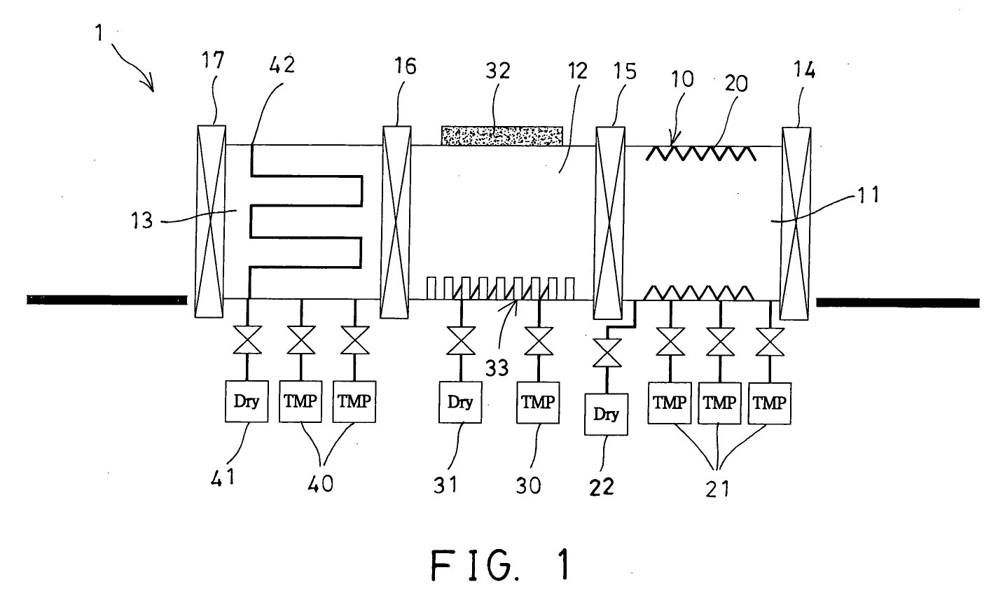

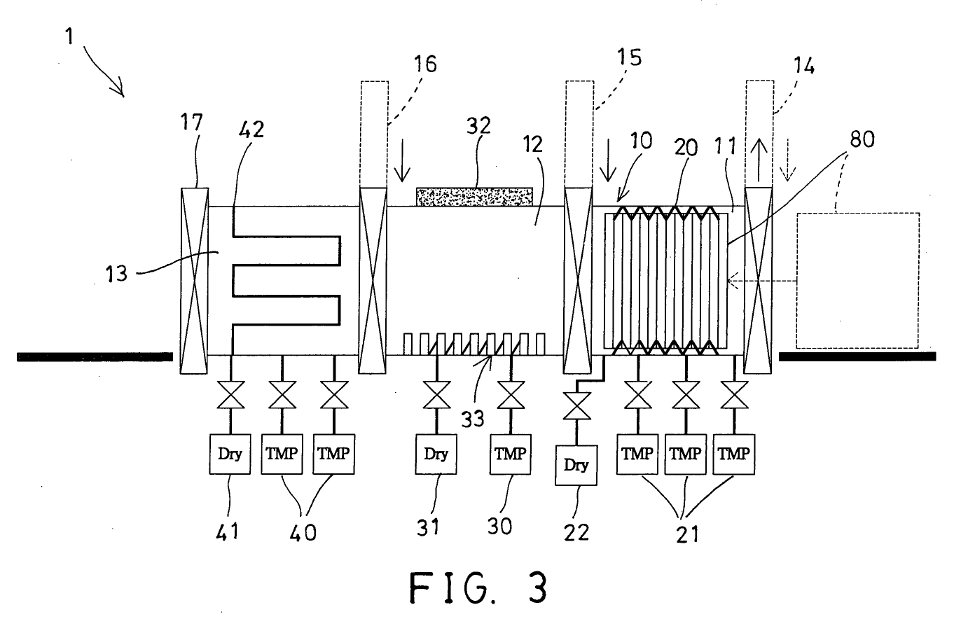

Referring to the drawings, and initially to FIG. 1, a plasma enhanced chemical vapor deposition apparatus 1 in accordance with the present invention comprises a vacuum receptacle 10 including three chambers 11, 12, 13 disposed or arranged side by side, and the chamber 11 is arranged as the first or the entering chamber 11, the other chamber 12 is arranged as the second or the intermediate chamber 12, and the further chamber 13 is arranged as the third or the exit chamber 13, for selectively receiving the substrates 80, 81, 82, 83 . . . (FIGS. 3-8), and for allowing the substrates 80-83 to be subjected or conducted or operated with the plasma enhanced chemical vapor deposition processes or procedures.

Four doors or gates 14, 15, 16, 17 are disposed or arranged beside or between the chambers 11, 12, 13 for selectively blocking or closing the chambers 11, 12, 13 respectively, for example, the first gate 14 is disposed or arranged before the first or the entering chamber 11, the second gate 15 is disposed or arranged between the first and the second chambers 11, 12, the third gate 16 is disposed or arranged between the second and the third chambers 12, 13, and the fourth gate 17 is disposed or arranged behind the third chamber 13, for allowing either or some of the chambers 11, 12, 13 to be selectively vacuumed.

One or more heaters 20 are disposed or attached to the first or the entering chamber 11 for heating the substrates 80-83, and one or more turbulent molecular pumps (TMP) 21, such as three TMP pumps 21, and one or more further pumps 22, such as a dry pump 22 are attached or coupled to the first chamber 11 for suitably vacuuming the first chamber 11, when the first chamber 11 is closed by the gates 14, 15. Similarly, one or more TMP pumps 30 and one or more dry pumps 31 are attached or coupled to the second chamber 12 for suitably vacuuming the second chamber 12, when the second chamber 12 is closed by the gates 15, 16.

A gas supply device 32 is attached or coupled to the second chamber 12 for suitably supplying the air or gas required for the PEVCD processes or procedures into the second chamber 12, and a high frequency electrode 33 is disposed or attached to the second chamber 12 for generating or providing an electric field to act on the air or gas, the substrates 80-83 or the like. Similarly, one or more TMP pumps 40 and one or more dry pumps 41 are attached or coupled to the third chamber 13 for suitably vacuuming the third chamber 13, when the third chamber 13 is closed by the gates 16, 17. A cooling device 42 is disposed or attached to the third chamber 13 for cooling the substrates 80-83.

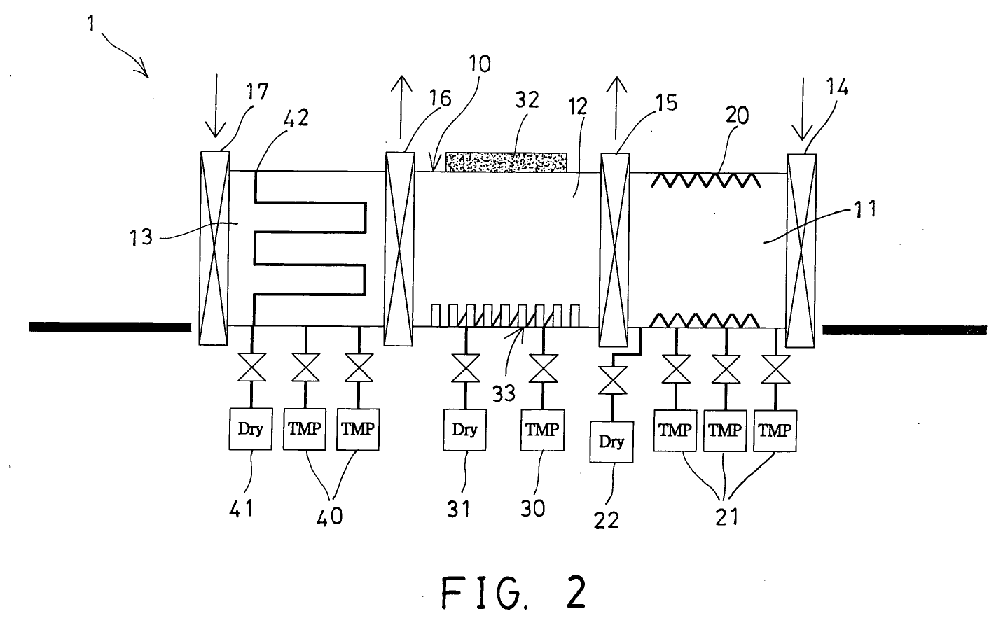

In operation, as shown in FIG. 2, the first gate 14 and the fourth gate 17 are closed, and the second gate 15 and the third gate 16 are opened for allowing the three chambers 11-13 of the receptacle 10 to be closed by the first gate 14 and the fourth gate 17. The dry pumps 22, 31, 41 are then energized or operated to vacuum the chambers 11-13 of the receptacle 10 up to about a pressure or a degree of vacuum of e-2 torr, and the TMP pumps 21, 30, 40 are then energized or operated to further vacuum the chambers 11-13 of the receptacle 10 up to about a degree of vacuum of e-6 torr.

Referring next to FIG. 3, the second gate 15 and the third gate 16 are then closed, and the first gate 14 is opened, the first platter or substrate 80 is then moved or sent into the first chamber 11, and the first gate 14 is then closed again, the first chamber 11 is then vacuumed to about a degree of vacuum of 4.6 e-5 torr. The heaters 20 are then energized or operated to heat the substrate 80 up to a temperature of about 230° C., and maintain the temperature for about two hours. Alternatively, the second gate 15 and the fourth gate 17 may first be closed, the first substrate 80 is moved into the first chamber 11, and the first gate 14 is then closed for preventing the first chamber 11 from being vacuumed before the first substrate 80 is moved into the first chamber 11.

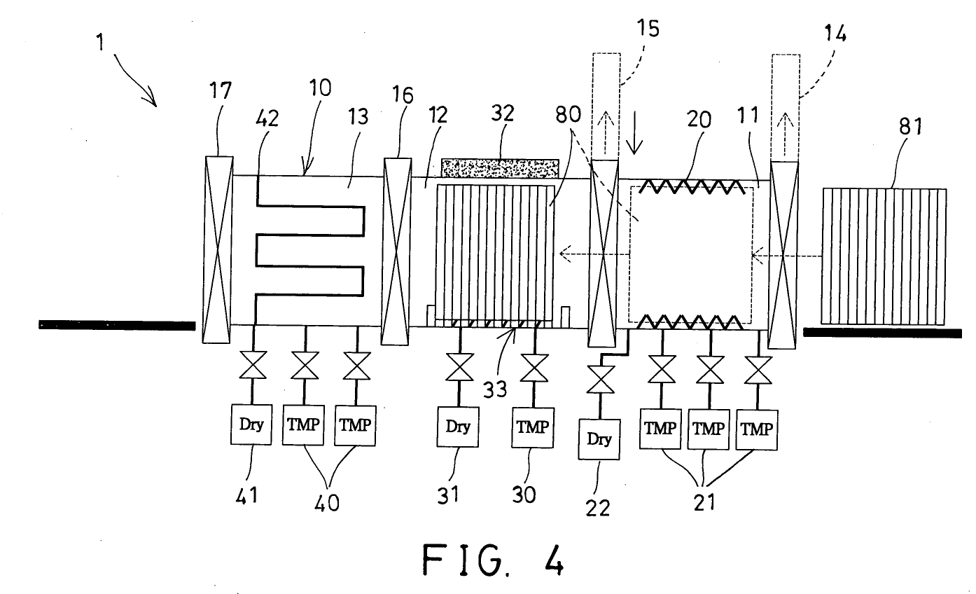

Referring next to FIG. 4, the second gate 15 is then opened, and the first platter or substrate 80 is then moved or sent into the second chamber 12, the second gate 15 is then closed again to retain the first substrate 80 within the second chamber 12, the gas supply device 32 is then energized or operated to supply the air or gas required for the PEVCD processes or procedures into the second chamber 12, and the high frequency electrode 33 is energized or operated to generate or provide an electric field to act onto the air or gas for allowing the treated air or gas to be deposited onto the outer peripheral portion of the first substrate 80. The PEVCD processes or procedures are preferably lasted for about 2.5 hours. While treating the first substrate 80 with the PEVCD processes or procedures in the second chamber 12, the first gate 14 may be opened, and the second platter or substrate 81 may then be moved or sent into the first chamber 11, and the first gate 14 may then be closed again for time saving purposes.

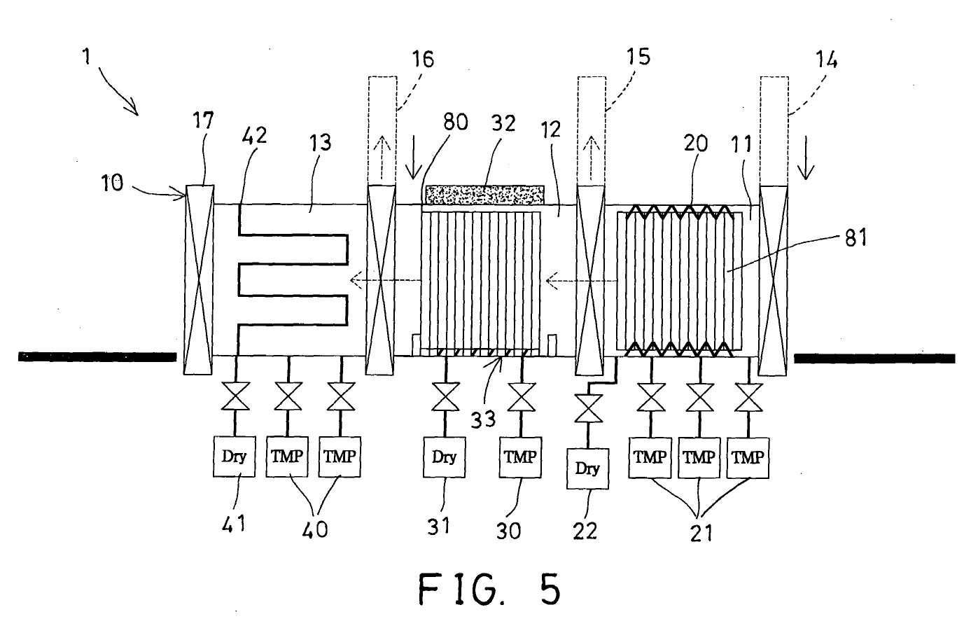

Referring next to FIG. 5, after the second substrate 81 has been moved or sent into the first chamber 11, and the first gate 14 may then be closed again, the first chamber 11 is then vacuumed with the pumps 21, 22 and is heated with the heaters 20. While the first chamber 11 is vacuumed and heated, the third gate 16 may be opened, the first substrate 80 is then moved or sent into the third chamber 13, and the cooling device 42 may then be energized or operated to cool the first substrate 80 for about one and a half hours. After the first substrate 80 has been moved into the third chamber 13 and closed by the third gate 16, the second gate 15 may then be opened and second substrate 81 may then be moved or sent into the second chamber 12, and the second gate 15 may then be closed again to retain the second substrate 81 within the second chamber 12.

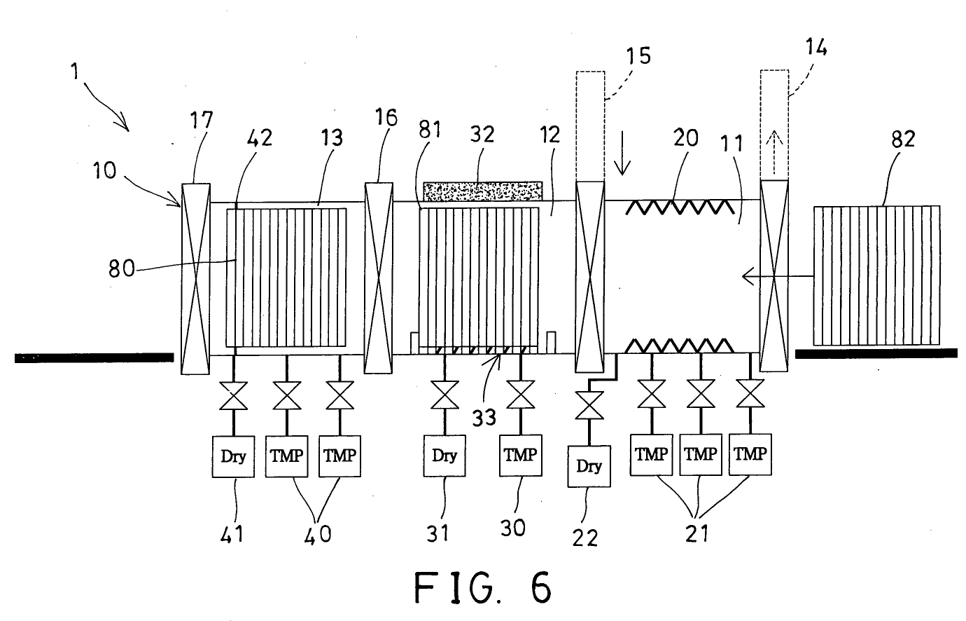

Referring next to FIG. 6, after the second substrate 81 has been moved or sent into the second chamber 12 and the second gate 15 is then closed again, the second substrate 81 that is retained within the second chamber 12 may then be treated or conducted with the PEVCD processes or procedures, and while treating the second substrate 81 with the PEVCD processes or procedures in the second chamber 12, the first gate 14 may be opened, and the third platter or substrate 82 may then be moved or sent into the first chamber 11, and the first gate 14 may then be closed again for time saving purposes.

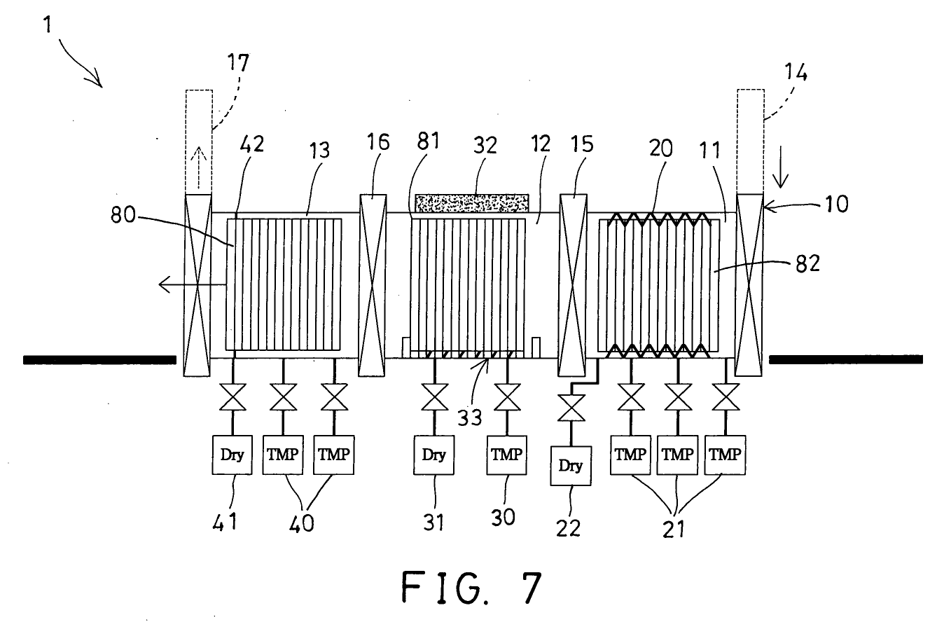

Referring next to FIG. 7, after the third substrate 82 has been moved or sent into the first chamber 11, and the first gate 14 may then be closed again, the first chamber 11 is then vacuumed with the pumps 21, 22 and is heated with the heaters 20. At this moment, the first substrate 80 is cooled within the third chamber 13, and the second substrate 81 be treated with the PEVCD processes or procedures within the second chamber 12 for time saving purposes. After the first substrate 80 has been cooled, the fourth gate 17 is opened, and the first substrate 80 is then moved out of the third chamber 13.

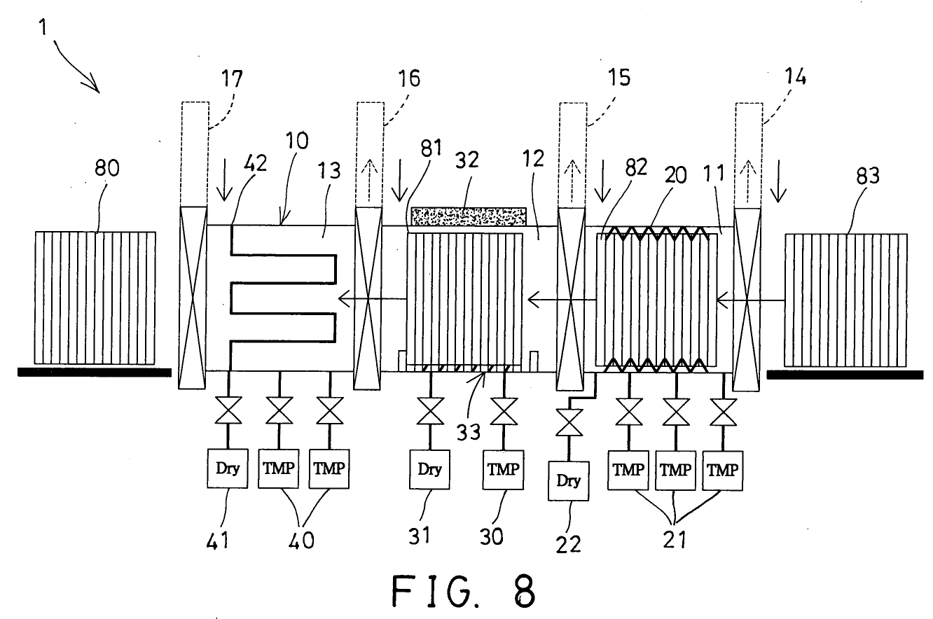

Referring next to FIG. 8, after the third substrate 82 has been moved out of the third chamber 13, the fourth gate 17 may then be closed again, and the pumps 40, 41 may then be energized or operated again to vacuum the third chamber 13 up to about a pressure or a degree of vacuum of 8.5 e-6 torr, the third gate 16 may then be opened and second substrate 81 may then be moved or sent into the third chamber 13 for being cooled with the cooling device 42, the third gate 16 may then be closed again, and the second gate 15 may then be opened for allowing the third substrate 82 to be moved or sent into the second chamber 12 for being treated with the PEVCD processes or procedures.

It is to be noted that the substrate 80 received in the third chamber 13 may be cooled with the cooling device 42, and the substrate 81 received in the second chamber 12 may be treated with the PEVCD processes or procedures, and simultaneously, the substrate 82 received in the first chamber 11 may be vacuumed with the pumps 21, 22 and may be heated with the heaters 20, such that the time for treating the substrate 80-83 may be greatly saved or economized, and the productivity may be greatly increased, and the substrate 80-83 may be suitably maintained in the vacuumed chambers 11-13 while conducting with the PEVCD processes or procedures and the heating and the cooling processes or procedures.

It is further to be noted that the vacuum receptacle 10 may include one or more first or the entering chambers 11 for heating the substrates 80-83, and one or more second or the intermediate chamber 12 for conducting with the PEVCD processes or procedures, and one or more third or exit chambers 13 for cooling the substrates 80-83 and for allowing the time for treating the substrate 80-83 to be further greatly saved or economized. The plasma enhanced chemical vapor deposition apparatus in accordance with the present invention may be provided for making such as solar cells, discs or the like.

Accordingly, the plasma enhanced chemical vapor deposition apparatus in accordance with the present invention includes three chambers disposed or arranged side by side for facilitating the operating processes or procedures for the plasma enhanced chemical vapor deposition apparatus and for reducing the operating time for the plasma enhanced chemical vapor deposition apparatus.

Although this invention has been described with a certain degree of particularity, it is to be understood that the present disclosure has been made by way of example only and that numerous changes in the detailed construction and the combination and arrangement of parts may be resorted to without departing from the spirit and scope of the invention as hereinafter claimed.

I claim:

1. A plasma enhanced chemical vapor deposition apparatus comprising:
a receptacle including a first chamber as an entering chamber, a second chamber as an intermediate chamber, a third chamber as an exit chamber, said second chamber being arranged between said first chamber and said third chamber for selectively receiving substrates,
a first gate disposed before said first chamber for closing said first chamber,
a second gate disposed between said first and said second chambers for closing said first chamber,
a third gate disposed between said second and said third chambers for closing said second chamber,
a fourth gate disposed behind said third chamber for closing said second chamber and for allowing said first and said second and said third chambers to be selectively vacuumed,
at least one first pump coupled to said first chamber for vacuuming said first chamber,
at least one second pump coupled to said second chamber for vacuuming said second chamber,
at least one third pump coupled to said third chamber for vacuuming said third chamber,
a gas supply device coupled to said second chamber for supplying a gas into said second chamber and treating the substrates with a plasma enhanced chemical vapor deposition process, and
an electrode attached to said second chamber for generating an electric field to act on the gas and the substrates.

2. The plasma enhanced chemical vapor deposition apparatus as claimed in claim 1, wherein said at least one first pump and said at least one second pump and said at least one third pump are dry pumps.

3. The plasma enhanced chemical vapor deposition apparatus as claimed in claim 1, wherein said at least one first pump and said and said at least one second pump and said at least one third pump are turbulent molecular pumps.

4. The plasma enhanced chemical vapor deposition apparatus as claimed in claim 1, wherein said receptacle includes at least one heater attached to said first chamber for heating the substrates.

5. The plasma enhanced chemical vapor deposition apparatus as claimed in claim 1, wherein said receptacle includes at least one cooling device attached to said third chamber for cooling the substrates.
